(19) United States
(12) Patent Application Publication
(10) Pub. No.: US 2006/0164817 A1
(43) Pub. Date: Jul. 27, 2006

(54) Communication module

(76) Inventor: Kyouhiro Yoshida, Osaka (JP)

Correspondence Address: FISH & RICHARDSON P.C., P.O. BOX 1022, MINNEAPOLIS, MN, 55440-1022, US

(21) Appl. No.: 10/562,630

(22) PCT Filed: Jun. 7, 2004
(86) PCT No.: PCT/JP04/07922

§ 371 Date: Dec. 23, 2005

(30) Foreign Application Priority Data
Jun. 26, 2003 (JP) 2003-182998

(51) Int. Cl. H05K 7/06; H01L 23/48

(52) U.S. Cl. 361/749; 174/254; 174/260; 257/723

(57) ABSTRACT

A communication module that may be smaller in size but capable of providing a high-rate communication with an excellent high frequency characteristic includes a semiconductor laser (LD) (10); a flexible printed circuit board (FPC) (11) on which the LD (10) is mounted and to which the LD (10) is electrically connected; a stem (12) through which the FPC (11) is inserted and to which the FPC (11) is then fixed; and a cap (13) so disposed as to cover the LD (10). The FPC (11) is used, instead of lead pins, to supply a power to the LD (10), derive signals therefrom and so on, whereby the high frequency characteristic can be improved. In addition, employment of a package structure comprising the stem (12) and cap (13) realizes the smaller size.

### TECHNICAL FIELD

The present invention relates to a communication module that has a package structure comprising a stem and a cap, and in particular, to a communication module that exhibits an excellent high frequency characteristic, allows a high rate communication to be performed, and that is the most suitable for optical communications.

### BACKGROUND ART

As a communication module conventionally used for optical communications, one is known whose structure is generally called CAN type package, for example. FIG. 6 (A) is a front elevational view of the longitudinal cross-sectional structure of a conventional optical receiver module, and FIG. 6 (B) is a plan view of a stem thereof as viewed from a BOARD connection side. The optical receiver module 100 as shown in FIG. 6 (A) includes a photodiode (PD) 101, the stem 102 bearing the PD 101, and a cap 104 having, in its top portion, a light-collective lens 103 and so disposed as to cover the PD 101. The PD 101, which is mounted on a sub-mount 105 fixed on the stem 102, receives, via the light-collective lens 103, an incident light from an optical fiber 200 fixed above the lens 103.

The stem 102 includes a plurality of holes 102a through which respective lead pins 106, which supply a power to the PD 101 and derive electric signals therefrom, are inserted. Fixing materials 107, made of solder, low-melting glass or the like, are used to fix the respective inserted lead pins 106, thereby maintaining hermeticity and mechanical strength. Further, wires 108 are used to provide electrical connections between the PD 101 and its associated lead pins 106 and between the sub-mount 105 and its associated lead pins 106.

FIG. 7 is a side view showing a state in which the conventional optical receiver module is connected to the BOARD. As shown in FIG. 7, the optical receiver module 100 is mounted on the BOARD 110 (i.e., a subsequent-stage circuit board) on which a preamplifier 109, which amplifies the electric signals from the PD 101, and other electronic circuit components (not shown) are implemented. Mounting the optical receiver module 100 on the BOARD 110 is achieved by bending the lead pins 106 of the optical receiver module 100 and then soldering the respective one ends of the lead pins 106 to corresponding wiring patterns 111 formed on the BOARD 110. A wire 112 is used to connect a wiring pattern 111 to the preamplifier 109, whereby the PD 101 is connected to the preamplifier 109 through the lead pin 106, wiring pattern 111 and wire 112.

Such optical receiver modules having the structure as described above are capable of providing communications of up to 100 Mbps and hence are in widespread use. In recent years, however, communication modules that are capable of providing communications of higher rates than 100 Mbps and that are smaller in size have been desired. Achieving such a higher-rate communication requires an improvement of the high frequency characteristics of communication modules. Then, there exists a technology for reducing the lengths of lead pins to reduce the inductances and capacitances in the previously described structure called CAN type package (See Patent Publication 1). Patent Publication 2 also discloses a communication module wherein the lengths of lead pins have been reduced.

Patent Publication 1: Japanese Official Gazette of Patent Laid-Open Publication No. 2001-196766

Patent Publication 2: Japanese Official Gazette of Patent Laid-Open Publication No. 2001-298217

### DISCLOSURE OF INVENTION

Problem to be Solved by the Invention

There is, however, a problem that the conventional communication modules employing the foregoing structure called CAN type package have a limitation of improvement of the high frequency characteristics and hence has a difficulty in achieving higher-rate communications.

As shown in the Patent Publications 1 and 2, a reduction of the lengths of the lead pins can somewhat improve the high frequency characteristics. However, when workability of mounting the communication module on the BOARD is taken into account, it is found that the lead pins need some lengths and hence the improvement of the high frequency characteristics as achieved by reducing the lead pin lengths is limited.

The high frequency characteristic can be also improved by changing, instead of the lead pin lengths, the sizes of the fixing materials, made of solder, low-melting glass or the like, that fix the respective lead pins to the stem. The high frequency characteristic is dependent on the permittivity E of the fixing materials 107 and on the diameters R thereof (See FIG. 6 (B)). Specifically, the high frequency characteristic can be improved by increasing the ratio of the fixing materials 107 to the lead pins 106; that is, reducing the diameters r of the lead pins 106, while increasing the diameters R of the fixing materials 107. However, the size (diameter t) of the stem 102 is specified in accordance with an optical connector to be coupled. Therefore, even if the diameters R of the fixing materials 107 are increased relative to the diameter t of the stem 102 in such a manner as to establish an impedance matching with external electronic circuit components implemented on the BOARD with the aim of improving the high frequency characteristic, then the sizes of the holes 102a to be formed in the stem 102 would be increased, resulting in a degradation of the mechanical strength of the stem 102, which would not be practical.

A communication module is known which has, instead of the structure called CAN type package, a so-called butterfly structure in which a PD, a semiconductor laser (LD) and so on are directly mounted on a circuit board on which high frequency lines, such as micro strip lines or the like, are formed. This module can provide a precise impedance matching with external electronic circuit components, but it is larger in size than one having the so-called CAN type package structure comprising a stem and a cap and hence is not appropriate in a case where a smaller size of communication module is desired.

It is an object of the present invention to provide a communication module that is smaller in size but capable of providing a high-rate communication with an excellent high frequency characteristic.

Means for Solving Problem

The present invention achieves the above-described object by employing a package structure, which comprises a stem and a cap, and further using no lead pins but using a flexible printed circuit board.

A communication module according to the present invention comprises a semiconductor member; a flexible printed circuit board on which the semiconductor member is mounted and to which the semiconductor member is electrically connected; a stem through which the flexible printed circuit board is inserted and to which the flexible printed circuit board is then fixed; and a cap so disposed as to cover the semiconductor member.

The communication module of the present invention having the structure described above employs, as members for supplying a power, deriving electric signals and so on, not lead pins but the flexible printed circuit board, so that the communication module is not affected by the lead pin lengths and the sizes of the fixing materials used for fixing the lead pins to the stem and hence can exhibit an improved high frequency characteristic. Further, since the communication module of the present invention employs the flexible printed circuit board that allows an impedance matching with the external electronic circuit components to be precisely established, it can have not a butterfly structure but a package structure comprising a stem and a cap, so that the size of the communication module can be further reduced. Thus, the communication module of the present invention is smaller in size but can provide communications of higher rates than 100 Mbps, particularly, than 1 Gbps.

Moreover, the communication module of the present invention employs the flexible printed circuit board to connect the semiconductor member to the BOARD, so that no short circuit occurs due to an accidental mutual contact of flexible printed circuit boards, or due to an accidental contact of the flexible printed circuit board with metallic dust, a metallic seal provided along the periphery of the package, or the like. The lead pins of the conventional communication modules as shown in FIGS. 6 and 7 are usually made of a highly conductive metal, such as copper, aluminum and so on, and the surfaces of such metals, except the portions thereof contacting with the fixing materials used for fixing them to the stem, are exposed. Accordingly, there is a fear that metallic dust, a metallic seal or the like accidentally contacts with lead pins connected to the BOARD and residing between the stem and the BOARD, causing those lead pins to be electrically connected to each other, resulting in occurrence of a short circuit. Moreover, all the portions of the lead pins, connected to the BOARD, except their portions fixed to the stem and to the BOARD, that is, those portions of the lead pins which reside between the stem and the BOARD can move to some degree. Accordingly, there is a fear that those movable portions accidentally contact with each other, resulting in occurrence of a short circuit. On the other hand, the flexible printed circuit board usually has a structure in which an insulating member (i.e., a cover lay) overlie the entire surfaces of the flexible printed circuit board except particular portions thereof, for example, those where semiconductor members or the like are mounted. Thus, even if flexible printed circuit boards accidentally contact with each other or with metallic dust, a metallic seal or the like, it will cause no short circuits. Therefore, the communication module of the present invention can prevent any damages from occurring due to such accidental short circuits. The prevent invention will be described below in greater detail.

A semiconductor member included in the communication module of the present invention may be a light emitting element when the communication module is an optical transmitter module. The light emitting element is, for example, a semiconductor laser (LD), a light emitting diode (LED) or the like, which may be made of AlGaAs system or InGaAsP system. When the communication module of the present invention is an optical receiver module, a semiconductor member included in the communication module may be a light receiving element. The light receiving element is, for example, a photodiode (PD), an avalanche photodiode (APD) or the like, which may be made of InGaAs system, InGaAsP system, Si, Ge or the like. Specifically, in a case of using a light receiving layer that receives long-wavelength bands, such as bands of wavelengths from 1 μm to 1.6 μm, the light receiving element is preferably made of InGaAs system, InGaAsP system or Ge. In a case of using a light receiving layer that receives shorter-wavelength bands, the light receiving element may be made of Si or the like. As the light receiving element to be used, front-illuminated type photodiode is preferable because it is easy to implement. When the communication module of the present invention is an optical transmitter/receiver module, it may include the same number of light emitting elements and light receiving elements described above. In any one of the above-described cases, when the communication module of the present invention is a communication module of multi-channel having a plurality of optical transmission media, such as optical fiber and the like, it may include a plurality of light emitting elements and light receiving elements in accordance with the number of the optical transmission media used. The semiconductor member may include various electronic elements used for communications and may be an integrated circuit (IC) in which such elements are electrically connected. For example, at the receiving end, such an integrated circuit may be an amplifier for amplifying the output electric power of the light receiving element, which is typically a preamplifier IC or a limiting amplifier IC. At the transmitting end, such an integrated circuit may be a driving element, such as a driver IC for driving the light emitting element.

The semiconductor member described above is mounted on a flexible printed circuit board. This flexible printed circuit board may have a typical structure in which one or more layers of wiring patterns comprising conductors, such as copper films or the like, are formed on a surface of, or the surface of and within an insulative basic material made of resin, such as polyimide, polyester or the like, and in which an insulative cover made of resin, such as polyimide, polyester or the like, is formed over the surfaces of that basic material.

The flexible printed circuit board may include at least one wiring pattern, and the number of such wiring patterns may be appropriately modified in accordance with the number of semiconductor members to be electrically connected to the flexible printed circuit board. A single flexible printed circuit board may have a plurality of wiring patterns formed therein, which may be connected to respective different semiconductor members. For example, in a case of a transmitter/receiver module, a single flexible printed circuit board may include different wiring patterns used for respective ones of light emitting and receiving elements. As another example, in a case of a transmitter module, a single flexible printed circuit board may include a wiring pattern used for a light emitting element and a wiring pattern used for a monitoring light receiving element that can determine the strength of a light emitted by the light emitting element. In a case of a receiver module, a single flexible printed circuit board may include a wiring pattern used for a light receiving element and a wiring pattern used for an amplifier that amplifies an electric signal outputted by the light receiving element. Thus, a plurality of semiconductor members may be mounted on a single flexible printed circuit board, so that there is no need to form a plurality of fixing holes in the stem as conventionally done. This reduction of the number of fixing holes can contribute to an improvement of the strength of the stem.

The flexible printed circuit board is inserted through the stem and then fixed thereto. Specifically, the flexible printed circuit board may be fixed to the stem with one of its ends protruding toward a side where the cap is located (which will be referred to as “cap side” hereinafter) and the other end protruding toward the opposite side (which will be referred to as “BOARD connection side” hereinafter). As another example, the flexible printed circuit board may be bent in such a manner that its bent portion protrudes from the stem toward the cap side, while its two ends protrude from the stem toward the BOARD connection side. When the flexible printed circuit board is fixed to the stem, a fixing material, such as solder or a glass of a low melting point, may be used. A fixing material may be appropriately selected which has a lower melting point than the material used to constitute the flexible printed circuit board, with the heat-resistance thereof taken into account. For example, when the flexible printed circuit board is made of polyimide, a fixing material whose melting point is on the order of 300 to 350 degrees centigrade may be appropriately used.

A portion of the flexible printed circuit board protracting from the stem toward the cap side will possibly bend by itself if it is left as it is. Then, a supporting member or the like is preferably provided to the stem. If the flexible printed circuit board is intentionally bent and disposed, a supporting member is preferably disposed inside such a bent portion of the flexible printed circuit board. Provision of such a supporting member can prevent the flexible printed circuit board from bending by itself even when a semiconductor member is mounted thereon, which facilitates the positioning relative to an optical transmission medium or the like. In addition, the provision of such a supporting member can reinforce the flexible printed circuit board. A material used to constitute the supporting member may be, for example, iron, such as cold-rolled steel sheet (SPC). The supporting member may be formed independently of the stem and fixed thereto by use of solder or the like. Alternatively, the supporting member may be integrally formed with the stem.

As described above, the number of wiring patterns to be formed in a single flexible printed circuit board may be increased so as to increase the number of components to be mounted on the single flexible printed circuit board. Alternatively, a plurality of different flexible printed circuit boards may be fixed to the stem such that different semiconductor members are mounted on the respective flexible printed circuit boards or such that the flexible printed circuit boards are used for different purposes with respect to a single semiconductor member. In the latter case, for example, a flexible printed circuit board used for a signal line of a semiconductor member may be differentiated from a flexible printed circuit board used for a ground line (GND line) or DC power supply line of that semiconductor member. In such a case, necessary wiring patterns have been formed in such flexible printed circuit boards. For example, the wiring pattern used for the GND line or DC power supply line has been preferably formed in such a manner that its line width is large. In a case when there is a fear that noise possibly occurs between signal lines if included in the same single flexible printed circuit board or between a signal line and a power supply line if included in the same single flexible printed circuit board, it is also preferable to employ a plurality of flexible printed circuit boards for respective different purposes.

Although the shape of the flexible printed circuit board to be employed is not specified, yet it is preferable that the flexible printed circuit board is suitably shaped beforehand for where it is to be located, because of ease with which to dispose the flexible printed circuit board there. For example, the possible shapes of the flexible printed circuit board when in a plane may include bent-shapes; specifically, L-shapes, S-shapes and so on.

At least a part of wiring patterns formed in the flexible printed circuit board is preferably a transmission line that can be used for a high frequency band. Such transmission lines may be a type of transmission lines selected from among, for example, coplanar lines, micro-strip lines and grounded coplanar lines. These lines can be formed by use of any known method.

The flexible printed circuit board is connected to a BOARD (i.e., a subsequent-stage circuit board) on which external electronic circuit components and the like are implemented. Although the connection of the flexible printed circuit board to the BOARD may be achieved by soldering, yet it also may be achieved by providing a connector, which can connect to the BOARD, to a BOARD connection side of the flexible printed circuit board and then connecting the connector to the BOARD. In this case, when electronic circuit components are fixed to the BOARD by reflow soldering, the connector can be also fixed thereto at the same time, with the result that the workability of assembly is improved. Moreover, in a case of connecting, by manual soldering, the flexible printed circuit board to the BOARD, if a semiconductor member, the flexible printed circuit board or the like suffers any damage, then not only it but also the BOARD must be replaced. In a case of using the connector to connect the flexible printed circuit board to the BOARD, only a removal of the connector would allow the BOARD to be reused, advantageously resulting in a cost reduction.

The communication module of the present invention has a package structure comprising a stem and a cap. The flexible printed circuit board is fixed to the stem. The cap is so disposed on the stem as to cover a semiconductor member mounted on the flexible printed circuit board that is fixed to the stem after having been inserted therethrough. The stem and cap are preferably made of metallic materials, such as iron (Fe), copper (Cu), or copper-nickel alloy (Cu—Ni), or iron alloy, for example, SPC, stainless, Fe—Co—Ni or the like. The package made of such metallic materials has a strong structure, exhibits an excellent long-term stability because of hermetic seal, also exhibits an excellent heat radiation, and also has a function of eliminating external electromagnetic noise.

In a case when the communication module includes a light emitting element or a light receiving element, the cap is preferably so constructed as to have therein a light-collective lens capable of coupling a light between a light transmission medium and the light emitting or receiving element, for the purpose of improving the workability of assembly. This lens may be any one that only can transmit therethrough the wavelength of a light from the light emitting element or to the light receiving element, and that may be made of a glass, for example, BK-7 (trade name) available from Schott, or the like.

As previously described, the communication module of the present invention may include, in addition to a light emitting element and/or a light receiving element, a monitoring light receiving element, an amplifier, a driving element and so on. The amplifier and driving element may be, for example, Si-IC, GaAs-IC or the like. In a case when the communication module includes an amplifier in addition to a light receiving element, the amplifier is preferably disposed in the vicinity of the light receiving element so that the length of a metallic wire, such as gold (Au), aluminum (Al) or the like, for connecting the amplifier to the light receiving element can be reduced, thereby enhancing the resistance to noise. As the foregoing monitoring light receiving element, one may be used which is similar to the light receiving element as described above.

### EFFECT OF THE INVENTION

As described above, the communication module of the present invention has the package structure, which comprises the stem and the cap, and employs, as members for supplying a power to a semiconductor member, deriving signals therefrom and so on, not lead pins but flexible printed circuit boards, thereby providing an excellent advantage that the high frequency characteristic can be improved regardless of the lengths of the lead pins and the sizes of the fixing materials used for fixing to the stem. Accordingly, the communication module of the present invention can be used for providing communications of higher rates than 100 Mbps, particularly, than 1 Gbps. Because of employing the flexible printed circuit board, the communication module of the present invention can provide a more precise impedance matching with external electronic circuit components, and yet it is smaller in size than the conventional one because of employing the package structure as described above.

### MODES FOR CARRYING OUT THE INVENTION

Embodiments of the present invention will be described below.

### EMBODIMENT 1

FIG. 1 is a schematic structure diagram illustrating an example of the communication module of the present invention having a light emitting element. A communication module 1 of the present embodiment includes an LD 10; a flexible printed circuit board (which will be referred to as “FPC” hereinafter) 11 on which the LD 10 is mounted and to which the LD 10 is electrically connected; a stem 12 through which the FPC 11 is inserted and to which the FPC 11 is then fixed; and a cap 13 so disposed as to cover the LD 10. Their structures will be described below in greater detail.

The LD 10 is a semiconductor device that emits a light, which is incident upon an optical fiber 200. In the present embodiment, the LD 10 is made of InGaAsP system. It should be noted that in the present embodiment, an excellent LD, which has been tested in advance, is used as the LD 10, so that deficiencies can be reduced.

The FPC 11 is a member on which the LD 10 is mounted and which is electrically connected to the LD 10 to supply a power thereto, derive signals therefrom and so on. In the present embodiment, the FPC 11 has a structure comprising an internal layer part 11a, which comprises a base material made of polyimide and which has, on and within the base material, wiring patterns comprising copper films, and insulative covers 11b made of polyimide and overlying the two surfaces of the internal layer part 11a. The FPC 11 is inserted through a fixing hole 12a formed in the stem 12 and then fixed thereto by use of a fixing material 15 with one of its ends protruding toward the cap 13 (the upper side of FIG. 1) and the other end protruding toward the BOARD (not shown) (the lower side of FIG. 1). In the present embodiment, a glass of a low melting point (300 degrees centigrade) is used as the fixing material 15.

A portion of the FPC 11, which protrudes toward the cap 13, bears the LD 10, which is electrically connected to a wiring pattern formed in the FPC 11. In the present embodiment, a part 11c of the FPC 11 on which the LD 10 is mounted has been rust-proofed and plated, and then a solder, the melting point of which is 300 degrees centigrade, has been used to fix the LD 10 to the part 11c. A bonding wire 14 made of gold is used to connect the LD 10 to the FPC 11. In the present embodiment, the wiring pattern to which the LD 10 is connected is of micro strip lines.

In the present embodiment, the stem 12 has a supporting member 16 for supporting the portion of the FPC 11 protruding toward the cap 13 so as to prevent that portion from bending by itself. The supporting member 16 may be anything that can support the portion of the FPC 11 protruding toward the cap 13 to prevent that portion from bending by itself. The supporting member 16 is a block of SPC and is fixed to the stem 12 by use of a solder in the present embodiment, but, alternatively, may be integrally formed with the stem 12.

A combination of the stem 12 and the cap 13 serves as a package for protecting the LD 10. The present embodiment employs, as this package, one which is made of stainless that exhibits an excellent mechanical-strength and an excellent heat radiation, can be hermetically sealed, and that has a function of eliminating electromagnetic noise. In the present embodiment, the central axis of the package is coaxial with the optical axis of the optical fiber 200. As described above, the FPC 11 is inserted through and then fixed to the hole 12a of the stem 12 by use of the fixing material 15. The cap 13 has a light-collective lens 13a for allowing a light from the LD 10 to be optically coupled to the optical fiber 200 with a high degree of efficiency. The light-collective lens 13a is so disposed that its central axis is coaxial with the optical axis of the optical fiber 200. The structures of the stem 12, cap 13 and light-collective lens 13a are the same as those in embodiments 2 and 3 that will be described later.

The present embodiment provides, on the stem 12, a monitoring PD 17 that can determine the strength of a light emitted from the LD 10. In the present embodiment, the monitoring PD 17, which is made of InGaAs system, is front-illuminated type photodiode, and is located under the LD 10 as shown in FIG. 1. The monitoring PD 17 is connected to the FPC 11 by use of a bonding wire 14.

The communication module of the present invention constructed as described above, though having the package structure of so-called CAN type, can exhibit an improved high frequency characteristic, regardless of the lead pin lengths and the sizes of the fixing materials, because of employing, as a member for supplying a power to the semiconductor device, deriving electric signals therefrom and so on, the FPC instead of lead pins. Further, because of employing the package structure of CAN type, the communication module of the present invention can be constructed in a smaller size than the conventional one having a block structure. In particular, the communication module of the present embodiment has, as wiring patterns formed in the FPC, transmission lines exhibiting an excellent high frequency characteristic, so that the impedance matching with the external electronic circuit components can be precisely established.

### EMBODIMENT 2

The foregoing embodiment was described as to a transmitter module having a light emitting element. The communication module of the present invention may be a receiver module having a light receiving element. FIG. 2 (A) is a schematic structure diagram illustrating an example of the communication module of the present invention having a light receiving element, and FIG. 2 (B) is a schematic diagram illustrating a magnified view of an FPC. Elements and members that are the same as those illustrated in FIG. 1 are designated by the same reference numbers. A communication module 2 of the present embodiment includes a PD 20; an FPC 11A on which the PD 20 is mounted and to which the PD 20 is electrically connected; an FPC 11B to which the PD 20 is electrically connected; a stem 12 through which the FPCs 11A and 11B are inserted and to which they are then fixed; and a cap 13 so disposed as to cover the PD 20. Their structures will be described below in greater detail.

The PD 20 is a semiconductor device that receives a light incident from an optical fiber 200. In the present embodiment, the PD 20, which is made of InGaAs, is front-illuminated type photodiode. It should be noted that in the present embodiment, an excellent PD, which has been tested in advance, is used as the PD 20, so that deficiencies can be reduced.

The present embodiment employs a plurality of FPCs each having a similar structure to the one of the FPC employed by the foregoing embodiment 1, and these FPCs 11A and 11B are fixed to the stem 12 by use of fixing materials 15. FIG. 2 shows two FPCs 11A and 11B, one of which, FPC 11B, is fixed to the stem 12 with one of its ends protruding toward the cap 13 and the other end protruding toward the BOARD (not shown) in a similar manner to the foregoing embodiment 1. The other FPC 11A is inserted through a hole 12a toward the cap 13, thereafter bent back, inserted again through another hole 12a, and then fixed to the stem 12. That is, as shown in FIG. 2 (A), the bent portion of the FPC 11A protrudes toward the cap 13, while the two ends thereof protrude toward the BOARD (not shown). As shown in FIG. 2 (B), the FPC 11A of the present embodiment is so constructed as to have an inner layer part 11a, which comprises a base material 22 made of polyimide and which has, on the two surfaces of and within the base material 22, a plurality of wiring patterns 23, and insulative covers 11b overlying the two surfaces of the inner layer part 11a. The PD 20 and a preamplifier IC 21, which amplifies an output from the PD 20, are fixed to respective different ones of the wiring patterns 23 of the FPC 11A by use of solder lid, the melting point of which is 300 degrees centigrade. It should be noted that parts 11c of the FPC 11A on which the PD 20 and preamplifier IC 21 are mounted have been rust-proofed and plated. Bonding wires 14 made of gold are used to provide electrical connections between the PD 20 and the FPC 11A and between the preamplifier IC 21 and the FPC 11A. In the present embodiment, the wiring pattern to which the PD 20 is connected and the wiring pattern to which the preamplifier IC 21 is connected are of coplanar lines. The preamplifier IC 21, which comprises Si-IC, is disposed in the vicinity of the PD 20 so as to reduce the length of a wire (not shown) which connects the preamplifier IC 21 to the PD 20, thereby reducing the affection of noise.

In the present embodiment, the FPC 11B is used as power supply lines for the PD 20 and preamplifier IC 21, and has wiring patterns that are larger in line width than those of the FPC 11A. Bonding wires made of gold are used to provide connections between the PD 20 and the FPC 11B and between the preamplifier IC 21 and the FPC 11B. (The bonding wire used for the latter connection is not shown.)

Similarly to the foregoing embodiment 1, the present embodiment employs a supporting member 16A, disposed inside the bent portion of the FPC 11A protruding toward the cap 13, for supporting the bent portion so as to prevent it from bending by itself. The supporting member 16A is a block of SPC and is fixed to the stem 12 by use of solder.

As described above, the communication module of the present invention may include a plurality of FPCs and a plurality of semiconductor members. Similarly to the foregoing embodiment 1, the present communication module can exhibit an improved high frequency characteristic and also can be constructed in a smaller size. Moreover, the communication module of the present embodiment has, as the wiring patterns formed in the FPC, transmission lines having an excellent high frequency characteristic, whereby the impedance matching with the external electronic circuit components can be readily established.

It should be noted that though the PD 20 and preamplifier IC 21 both are mounted on the FPC 11A in the present embodiment, they may be mounted on respective different FPCs. Specifically, the PD 20 may be mounted on the FPC 11A, while the preamplifier IC 21 may be mounted on the FPC 11B.

### EMBODIMENT 3

The foregoing embodiments 1 and 2 were described as to the transmitter module and the receiver module. The communication module of the present invention may be a transmitter/receiver module having both a light emitting element and a light receiving element. FIG. 3 is a schematic structure diagram illustrating an example of the communication module of the present invention having light emitting and receiving elements. Elements and members that are the same as those illustrated in FIGS. 1 and 2 are designated by the same reference numbers. A communication module 3 of the present embodiment includes an LD 10; an FPC 11C on which the LD 10 is mounted and to which the LD 10 is electrically connected; a PD 20; an FPC 11D on which the PD 20 is mounted and to which the PD 20 is electrically connected; a stem 12 through which the FPCs 11C and 11D are inserted and to which they are then fixed; and a cap 13 so disposed as to cover the LD 10 and PD 20. Their structures will be described below in greater detail.

The present embodiment employs two FPCs having similar structures to the ones of the FPCs employed by the foregoing embodiment 2. Each of the two FPCs is fixed to the stem 12 with one of its ends protruding toward the cap 13 and the other end protruding toward the BOARD (not shown) similarly to the foregoing embodiment 1. One of the two FPCs, namely FPC 11C, bears the LD 10 for transmission, while the other, namely FPC 11D, bears the PD 20 for reception. The present embodiment employs an optical path conversion part 30 capable of focusing and separating a light incident from the LD 10 upon an optical fiber 200 and a light outgoing from the optical fiber 200 toward the PD 20.

The optical path conversion part 30, which has a WDM (wavelength division multiplex) filtering function, includes a transmission/reflection part 30a that allows one of the incident and outgoing lights as described above to pass therethrough and reflects the other light. The transmission/reflection part 30a may be formed by using PVD or CVD methods to form a film over a surface of a substrate made of a transparent glass or the like. As to the materials of the film formed, the film comprises a multi-layered film of dielectric materials, which may alternately have a film of a low-refractive material, such as SiO₂, MgF₂ or the like, and a film of a high-refractive material, such as Al₂O₃, Ti₂O₅ or the like. In the present embodiment, a plasma CVD method (P-CVD method) is used to alternately deposit films of SiO₂ and Ti₂O₅ over a transparent glass substrate. The optical path conversion part 30 is fixed to a supporting member 16 that supports the FPC 11C. It should be noted that the incident and outgoing lights as described above have been caused to exhibit mutually different wavelengths. In the present embodiment, the former exhibits a wavelength of 1.3 μm and the latter exhibits a wavelength of 1.55 μm.

The LD 10 and PD 20, which are the same as those in the foregoing embodiments 1 and 2, are connected to the FPCs 11C and 1D, respectively, by use of bonding wires 14 made of gold. Supporting members 16 that support the FPCs 11C and 11D are integrally formed with the stem 12. The wiring pattern to which the LD 10 is connected and that to which the PD 20 is connected are of grounded coplanar lines. Additionally, in the present embodiment, the package includes a monitoring PD 17 and a preamplifier IC (not shown) that amplifies an output from the PD 20, and it may further include an IC for driving the LD 10, and the like.

As described above, the communication module of the present invention may be a transmitter/receiver module. Because of employing not lead pins but FPCs, this communication module can exhibit an improved high frequency characteristic and also can be constructed in a smaller size similarly to the foregoing embodiments 1 and 2. Moreover, the communication module of the present embodiment has, as the wiring patterns formed in the FPCs, transmission lines having an excellent high frequency characteristic, whereby the impedance matching with the external electronic circuit components can be readily established.

The foregoing embodiments 1 through 3 were described as having a light emitting element and/or a light receiving element, but as a matter of course, they may have a structure that includes only integrated circuits (ICs). In such cases, the cap may have no light-collective lens.

### EMBODIMENT 4

In the foregoing embodiments 1 through 3, solder or the like is used to connect the FPCs to the BOARD. Next, a structure that facilitates the connection to the BOARD will now be described. FIG. 4 is a schematic diagram illustrating a communication module of the present invention having a connector. Elements and members that are the same as those illustrated in FIG. 1 are designated by the same reference numbers. A communication module 4 of the present embodiment is the same as the communication module of the embodiment 1 in the basic structure but different in that it employs a connector 40 that is provided to a BOARD connection end of an FPC 11 and that can connect to the BOARD.

Because of the structure having the connector, when electronic circuit components are fixed to the BOARD by use of reflow soldering, the connector can be also fixed at the same time, whereby the workability of assembly is improved. Moreover, the connector is removable from the BOARD, and hence, if any trouble occurs in a constituent element, such as a semiconductor member or FPC, then the connector is removed, whereby the BOARD can be reused.

### EMBODIMENT 5

In the foregoing embodiments 1 through 4, examples employing FPCs having rectangular shapes when in a plane were described, but, as a matter of course, FPCs having different shapes may be employed. FIG. 5 is a schematic diagram illustrating a communication module of the present invention employing an FPC that is L-shaped when in a plane. Elements and members that are the same as those illustrated in FIG. 1 are designated by the same reference numbers. A communication module 5 of the present embodiment is the same as the communication module of the embodiment 1 in the basic structure but different in that an FPC 50 has a bent-shape when in a plane.

As described above, the communication module of the present invention may employ modified shapes of FPCs. Thus, the FPCs can be suitably shaped beforehand for where they are to be located. The present embodiment employs the FPC that is bent in an L-shape when in a plane, but, as a matter of course, any other shapes, such as S-shapes and so on, of FPCs may be employed.

### INDUSTRIAL APPLICABILITY

The communication module of the present invention is used for optical communications, and in particular, the most suitable for usages that require an excellent high frequency characteristic and a high rate communication.

### BRIEF DESCRIPTION OF THE DRAWINGS

FIG. 1 is a schematic structure diagram illustrating an example of the communication module of the present invention having a light emitting element.

FIG. 2 (A) is a schematic structure diagram illustrating an example of the communication module of the present invention having a light receiving element. FIG. 2 (B) is a schematic diagram illustrating a magnified view of an FPC.

FIG. 3 is a schematic structure diagram illustrating an example of the communication module of the present invention having light emitting and receiving elements.

FIG. 4 is a schematic diagram illustrating a communication module of the present invention having a connector.

FIG. 5 is a schematic diagram illustrating a communication module of the present invention employing an FPC that has a bent-shape when in a plane.

FIG. 6 (A) is a front elevational view of the longitudinal cross-sectional structure of a conventional optical receiver module. FIG. 6 (B) is a plan view of a stem as viewed from a BOARD connection side.

FIG. 7 is a side view showing a state in which the conventional optical receiver module is connected to the BOARD.

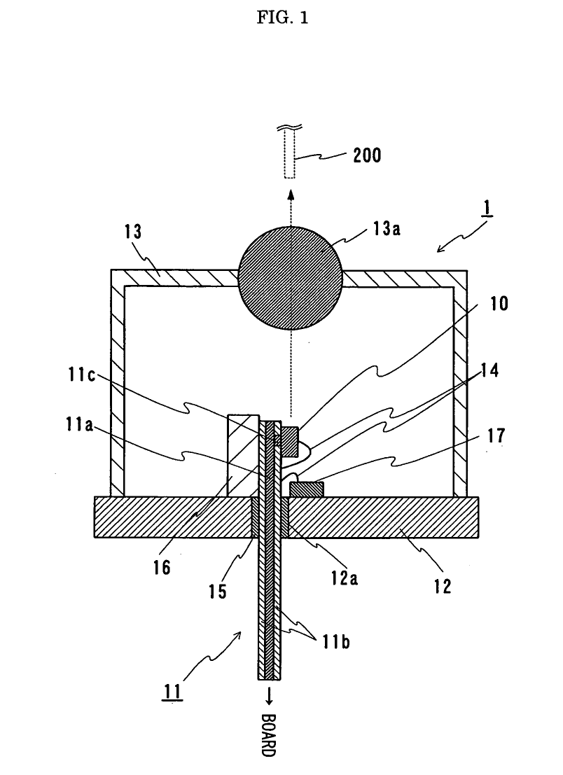

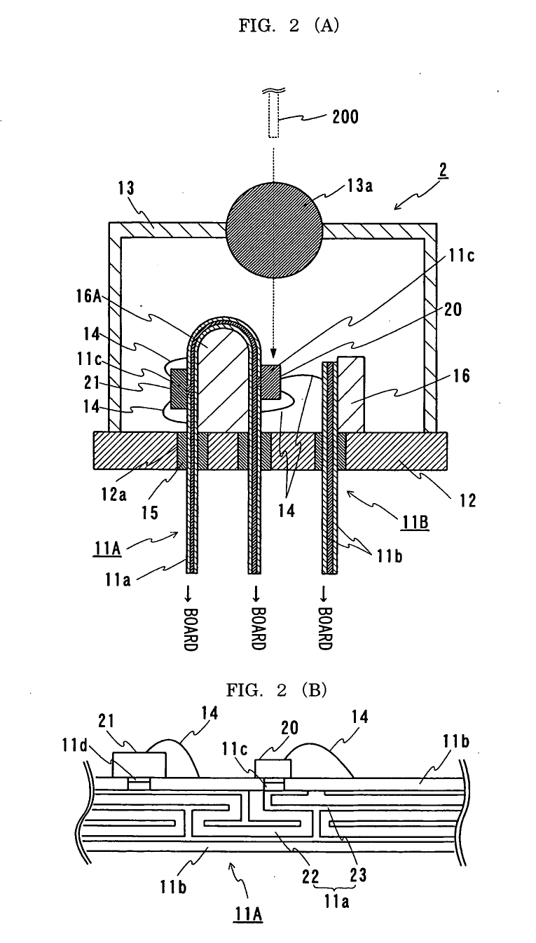

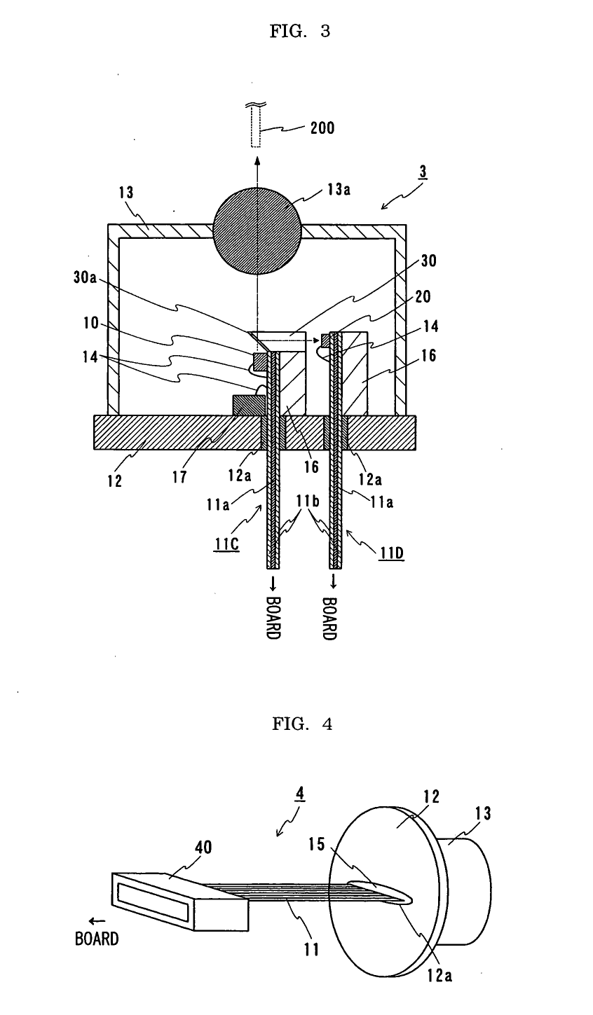

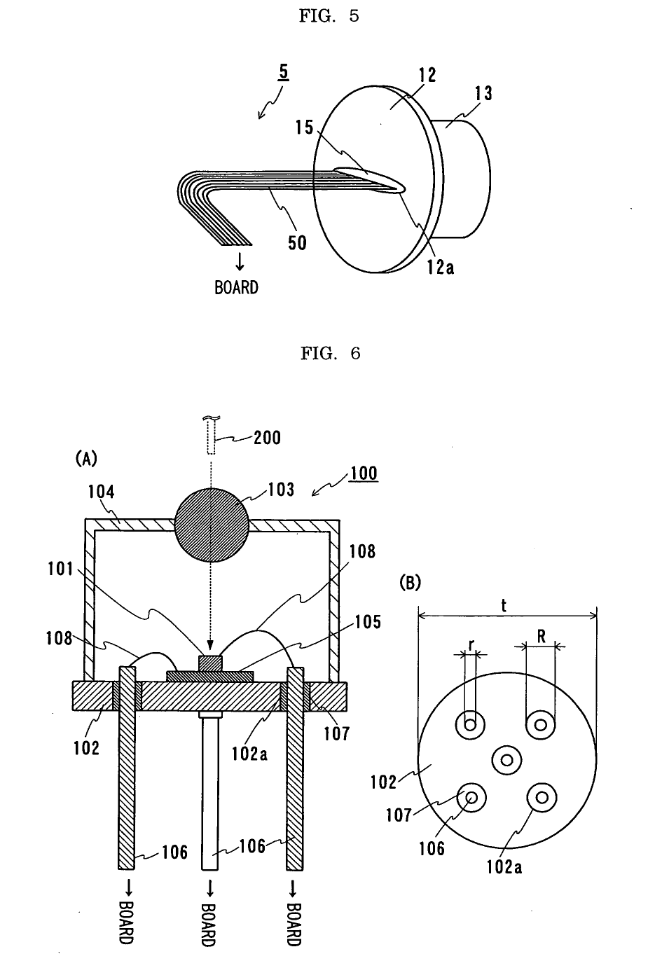

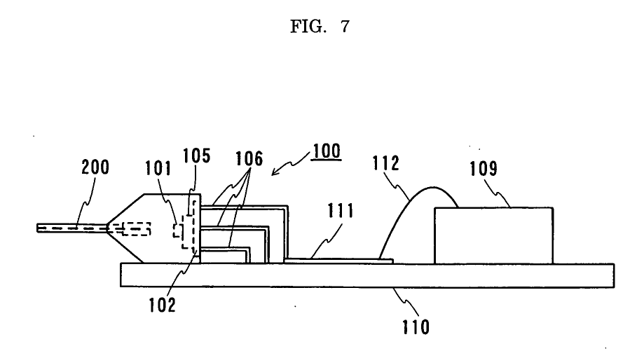

### EXPLANATIONS OF LETTERS OR NUMERALS

1,2,3,4,5 Communication module
10 LD 11,11A,11B,11C,11D,50 FPC
11a Internal layer part 11b Insulative covers
11c Part lid Solder 12 Stem 12a Hole
13 Cap 13a Light-collective lens 14 Bonding wire
15 Fixing material 16,16A Supporting member
17 Monitoring PD
20 PD 21 Preamplifier IC 22 Base material
23 Wiring patterns
30 Optical path conversion part
30a Transmission/Reflection part 40 Connector
100 Optical receiver module 101 PD
102 Stem 102a Hole 103 Light-collective lens
104 Cap 105 Sub-mount 106 Lead pin
107 Fixing material 108,112 Wire 109 Preamplifier
110 Board 111 wiring pattern
200 Optical fiber

1. A communication module comprising:
a semiconductor member;
a flexible printed circuit board on which said semiconductor member is mounted and to which said semiconductor member is electrically connected;
a stem through which said board is inserted and to which said board is then fixed; and
a cap so disposed as to cover said semiconductor member.

2. The communication module according to claim 1, wherein the semiconductor member is at least one of a light emitting element, a light receiving element and an integrated circuit.

3. The communication module according to claim 1, wherein the flexible printed circuit board includes a type of lines selected from among coplanar lines, micro-strip lines, and grounded coplanar lines.

4. The communication module according to claim 1, wherein a plurality of different flexible printed circuit boards are fixed to the stem.

5. The communication module according to claim 1, wherein an end of the flexible printed circuit board(s) that protrudes from the stem has a connector that can connect to a subsequent-stage circuit board.

6. The communication module according to claim 1, wherein the flexible printed circuit board(s) exhibits a bent-shape when in a plane.
